(19) United States
(12) Patent Application Publication
(10) Pub. No.: US 2003/0002263 A1
(43) Pub. Date: Jan. 2, 2003

(54) HDI circuit board and method of production of an HDI circuit board

(75) Inventor: Hans Hoffmann, Lauffen (DE)

Correspondence Address: SUGHRUE, MION, ZINN, MACPEAK & SEAS, PLLC, 2100 Pennsylvania Avenue, N.W., Washington, DC, 20037-3213, US

(73) Assignee: ALCATEL

(21) Appl. No.: 10/166,665

(22) Filed: Jun. 12, 2002

(30) Foreign Application Priority Data
Jul. 2, 2001 (EP) 01 440 200.2

(51) Int. Cl. H05K 1/00; H05K 1/18; H05K 7/02; H05K 7/06; H05K 7/08

(52) U.S. Cl. 361/748

(57) ABSTRACT

In a method for the production of multilayer High Density Interconnect (HDI) circuit boards, orientation points for the individual layers are arranged on an assembly frame outside the actual circuit board and a further orientation point is arranged on the actual circuit board as an origin for all layers. Thus smaller tolerances can be realized in production.

### BACKGROUND OF THE INVENTION

The invention is based on a priority application EP 01 440 200.2 which is hereby incorporated by reference. The invention relates to a method for the production of multilayer High Density Interconnect (HDI) circuit boards in which orientation points for the individual layers are arranged on an assembly frame outside the actual circuit board.

High Density Interconnect (HDI) circuit boards are taken to mean multilayer circuit boards with an average contact density of more than 20 pads/cm², with array grid masks of less than 1.0 mm and with microvias. Pads are terminal faces on the circuit board for electronic components. Here contact is made between the component connection and the electrical connections on the circuit board. A microvia is basically a connecting hole between the functional layers. In particular, through-vias, buried vias or blind vias with a diameter of less than 150 μm are described as microvias, regardless of the manner of production. Microvias can be filled with electrically conductive material to create an electrical connection between the layers.

When producing HDI circuit boards, films are used in typically up to 20 layers. However, even more than 20 layers can be used. These films and structures defined thereon e.g. by lithography and produced for example by etching processes are orientated to one another. Structures are taken to mean the electrical connections etched or cut from a complete copper surface. However, the structures can also be produced by printing. The layers are pressed together in one or more pressing steps. In particular, the microvias must also be correctly orientated, so that the various layers are connected conductively to one another at the correct points.

FIG. 2 shows a standard HDI circuit board (HDI printed board) 11. The actual circuit board 11 is surrounded by an assembly frame 12, which can be removed following completion of the circuit board. The circuit board 11 and the assembly frame 12 are formed as a single piece, i.e. the assembly frame is an edge area of the circuit board as a whole or of the individual films that is not provided with structures. The assembly frame 12 contains orientation points (registration marks) 13-16. The films of the various layers are orientated to the orientation points 13-16. The orientation point 13 serves as the origin (zero point) for the orientation of drilling, etching and exposure machines, for example, which are used in the production of the circuit board 1 to produce the structures on the circuit board 11. When producing the circuit boards 11, account has to be taken of the differences in expansion of the various layers that occur in particular on pressing of the layers. The differences in expansion are due to different materials used for the individual layers and to different layer thicknesses. These differences in expansion can be taken into account in production insofar as the expansion of the layer is taken into account in the definition of structures on the individual layers, so that the structures are located in the correct position when the circuit board is complete, i.e. following one or more pressing operations. What matters, therefore, is orientating the layers and structures as accurately as possible, i.e. with a small tolerance. On smaller circuit boards, e.g. 233 mm×160 mm or 233 mm×210 mm, sufficiently good tolerances could be achieved with the orientation points 3 to 6. However, on large HDI circuit boards, e.g. with the dimensions 500 mm×310 mm, no sufficiently good tolerances can be achieved with these orientation points, as the point 17 of the circuit board 11 located furthest away from the origin 13 is approximately d₁=\sqrt{1²+b²} away from the origin 13 and such a point cannot be approached sufficiently accurately by a machine, taking the expansion of the layers into consideration.

### SUMMARY OF THE INVENTION

The object of the present invention is therefore to provide a method for the production of HDI circuit boards with a smaller tolerance.

This object is achieved according to the invention by a method of the type stated at the beginning, in which a further orientation point is arranged on the actual circuit board as an origin for all layers.

Due to the definition of a new origin on the circuit board, production machines such as drilling or cutting machines can be orientated to this origin. The maximum path that a tool has to travel is reduced by this measure. Thus smaller tolerances can be realized.

In an advantageous variant of the method, the further orientation point is selected in the centre of the actual circuit board. If the further orientation point, i.e. the origin in the centre of the circuit board, is provided in particular on the point of intersection of the diagonals of the circuit board, the maximum path to be travelled by a tool in one direction is d₂=½\sqrt{1²+b²} and thus half of the maximum path to be travelled in production methods according to the prior art. Calculating the scaling of structures and the placing of structures for layers with different expansion can also be undertaken from this point. Starting out from this point, more accurate calculation with smaller tolerances can be carried out.

If all production steps are orientated to the further orientation point, the individual layers can be superimposed on one another with a considerably smaller tolerance.

In a further aspect of the invention, the object is achieved by an HDI circuit board on which at least one orientation point for orientation of the layers and/or structures during production of the circuit board is provided on the circuit board. The orientation point can be defined on a carrier plate prior to the start of production and/or defined on each layer of the HDI circuit board.

In a preferred configuration of the invention, the orientation point is arranged in the centre of the circuit board. An HDI circuit board with a particularly small tolerance can thus be produced.

If the HDI circuit board is surrounded by an assembly frame, which has further orientation points, orientation to the orientation point on the circuit board can be verified. In addition, non-critical layers, i.e. layers that can be orientated with greater tolerance, can be orientated to the orientation points of the assembly frame in a conventional manner.

A further aspect of the invention relates to an assembly device for producing an HDI circuit board using an orientation point on the circuit board.

### BRIEF DESCRIPTION OF THE DRAWINGS

Further advantages of the invention result from the description and the drawing. Likewise, the features stated here and explained further can be used according to the invention individually by themselves or severally in any combinations. The embodiment shown and described should not be regarded as a conclusive enumeration, but is rather of an exemplary character for describing the invention.

The invention is shown in the drawing and explained in greater detail with reference to a practical example.

FIG. 1 shows an HDI circuit board according to the invention with an orientation point;

FIG. 2 shows an HDI circuit board according to the prior art.

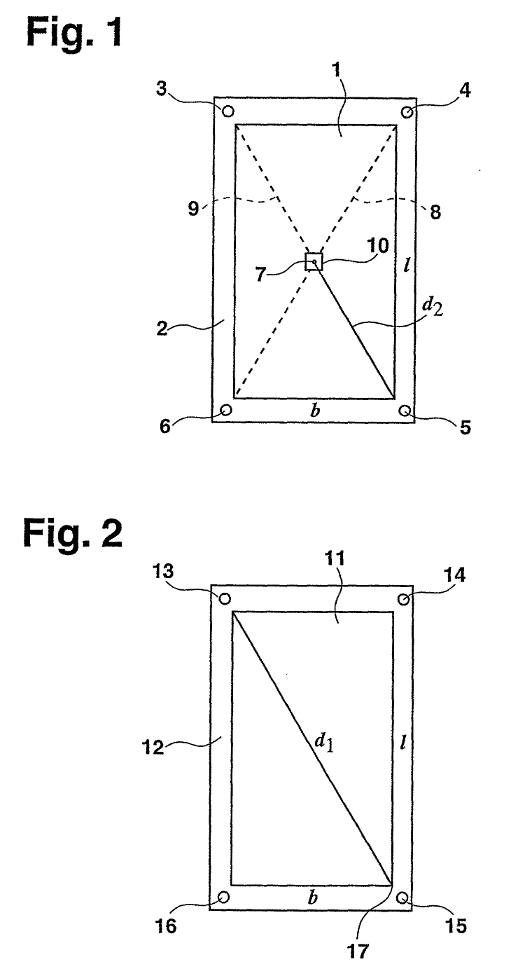

An HDI circuit board 1 is shown in FIG. 1. The actual circuit board 1 is surrounded by an assembly frame 2, which is removed on completion of the circuit board. Arranged on the assembly frame 2 are orientation points 3 to 6. In the example, they are located in the area of the corners of the rectangular assembly frame 2. The films of the various layers that can be orientated with a large tolerance can be orientated to the orientation points 3 to 6. At the point of intersection 7 of the diagonals 8, 9 of the circuit board 1 is a further orientation point 10, which serves as the origin for the registration (fit-accurate arrangement) of the layers that have to be orientated with a small tolerance, and for production tools. In the embodiment, the visually automatically recognizable orientation point 10 is formed as a circle, which is surrounded by a square frame, the circle lying on the point of intersection 7. The maximum path that is to be travelled by a production tool using the orientation point 10 as the origin is d₂=½\sqrt{1²+b²}.

The method of production of an HDI circuit board is to be explained with reference to an example. First a circuit board core of raw material, such as copper and epoxy resin-glass fabric (dielectric) is manufactured, one or both outer layers of the circuit board core being a copper layer depending on the structure of the circuit board. A registration mark (orientation point as origin) is applied in the centre of the circuit board core, in that either a hole, e.g. due to drilling or punching, or a structure, e.g. due to etching, cutting or processing by laser light, is created. A structure representing the registration mark can also be printed on. The registration mark can be produced beforehand or at the same time as the structuring of a copper layer on one or both sides of the circuit board core. Structuring of the copper layer(s) is achieved by mechanical drilling, cutting and processing by laser light or etching. The removal of copper creates islands that produce the electrical connections and are electrically insulated from one another. Dielectric layers are thereupon applied to both sides of the circuit board core. Microvias can then be produced by laser drilling, i.e. holes in the dielectric. The laser drilling is orientated to the registration mark in the centre of the circuit board. The microvias are lined with electrically conductive material in a metallizing process. Then a copper layer can be applied respectively to the dielectric layer(s). The copper layers are very thin layers that have already been structured in advance and applied to a carrier film. The copper layers also have a registration mark in the centre, to which the structuring has been orientated. If the copper layers are applied to the dielectric layers, they are orientated to the registration marks of the circuit board core. The copper layers are connected electrically conductively to the circuit board core via the microvias. The layers are then pressed together. So that the registration mark in the centre of the circuit board core can be used to orientate the individual layers to one another, it is located either by X-ray or exposed by cutting, etching or laser machining and then visually registered. If a hole is provided as a registration mark, it can be registered via a feeler. The method steps stipulated hitherto can be repeated until an HDI circuit board with approx. 20 layers is attained. Alternatively, multilayer layer stacks consisting of a combination of copper layers and dielectric that are produced analogously to the circuit board core are layered loosely on the circuit board core and then pressed together jointly. The assembly frame can then be removed by cutting and testing of the circuit board can be carried out.

1. Method for the production of multilayer High Density Interconnect (HDI) circuit boards, in which orientation points for the individual layers are arranged on an assembly frame outside the actual circuit board, wherein a further orientation point is arranged on the actual circuit board as an origin for all layers.

2. Method according to claim 1, wherein the further orientation point is selected in the centre of the actual circuit board.

3. Method according to claim 1 or 2, wherein all production steps are orientated to the further orientation point.

4. HDI circuit board, wherein at least one orientation point for the orientation of the layers and/or structures during production of the circuit board is provided on the circuit board.

5. HDI circuit board according to claim 4, wherein the orientation point is arranged in the centre of the circuit board.

6. HDI circuit board according to one of claims 4 or 5, wherein the HDI circuit board is surrounded by an assembly frame, which has further orientation points.

7. Assembly device for the production of an HDI circuit board according to one of claims 4 to 6 executing the method according to one of claims 1 to 3.
